(19) United States
(12) Patent Application Publication
(10) Pub. No.: US 2025/0149374 A1
(43) Pub. Date: May 8, 2025

(54) VACUUM HOLE CONNECTOR, SUBSTRATE SUPPORT, SUBSTRATE TREATMENT APPARATUS

(71) Applicant: SEMES CO., LTD., Cheonan-si (KR)

(72) Inventors: Jae Oh BANG, Seoul (KR); Min Young KIM, Hwaseong-si (KR); Ju Mi LEE, Seoul (KR)

(21) Appl. No.: 18/812,989

(22) Filed: Aug. 22, 2024

(30) Foreign Application Priority Data
Nov. 8, 2023 (KR) 10-2023-0153391

(51) Int. Cl. H01L 21/687; H01L 21/67

(52) U.S. Cl. CPC H01L 21/68785; H01L 21/67103; H01L 21/68742

(57) ABSTRACT

The present disclosure provides a vacuum hole connector, a substrate support, and a substrate treatment apparatus. A vacuum hole connector according to an embodiment of the present disclosure includes a first connection member fixed to a lower portion of a first vacuum hole of a heating plate, and in which a first connection hole is formed; and a second connection member installed in a second vacuum hole of a heater cup, attached to the first connection member, and in which a second connection hole is formed, wherein the first connection member and the second connection member include a metal material, and the first vacuum hole communicates with the second vacuum hole through the first connection hole and the second connection hole, when the first connection member and the second connection member are assembled.

### CROSS-REFERENCE TO RELATED APPLICATIONS

This application claims benefit of priority to Korean Patent Application No. 10-2023-0153391 filed on Nov. 8, 2023 in the Korean Intellectual Property Office, the disclosure of which is incorporated herein by reference in its entirety.

### BACKGROUND

### 1. Field

The present disclosure relates to a vacuum hole connector connecting a vacuum hole of a heating plate and a vacuum hole of a heater cup, a substrate support including the vacuum hole connector, and a substrate treatment apparatus including the substrate support.

### 2. Description of Related Art

To manufacture semiconductor devices, various processes such as a photography process, an etching process, a deposition process, an ion implantation process, a cleaning process, and the like may be performed. Among these processes, the photography process may be a process for forming patterns, and may play an important role in achieving a high degree of integration of the semiconductor devices.

The photography process may commonly include a coating process, an exposure process, and a development process, and a baking process may be performed before and after the exposure process. The baking process may be a process of heat treating a substrate. When the substrate is disposed on a heating plate, the substrate may be heat treated through a heater provided inside the heating plate.

A silicone rubber member may be disposed between the heating plate and a heater cup to connect a vacuum hole of the heating plate and a vacuum hole of the heater cup. However, such a silicone rubber member may have limitations in use thereof in a high-temperature substrate processing process, for example, a high-temperature baking process.

### PRIOR ART LITERATURE

### Patent Document

(Patent Document 1) Korea Patent Publication No. 10-2021-0052053

### SUMMARY

An aspect of the present disclosure is to provide a vacuum hole connector, a substrate support, and a substrate treatment apparatus that may be used without thermal damage even in a high-temperature substrate processing process.

According to an aspect of the present disclosure, a vacuum hole connector includes a first connection member fixed to a lower portion of a first vacuum hole of a heating plate, and in which a first connection hole is formed; and a second connection member installed in a second vacuum hole of a heater cup, attached to the first connection member, and in which a second connection hole is formed, wherein the first connection member and the second connection member include a metal material, and the first vacuum hole communicates with the second vacuum hole through the first connection hole and the second connection hole, when the first connection member and the second connection member are assembled.

The first connection member formed of the metal material may be joined to the heating plate formed of a ceramic material by active metal brazing (AMB), to form a joint of heterogeneous materials.

The first connection member may include a head joined to the heating plate; and an insertion bar extending from the head and inserted into the second connection hole of the second connection member, wherein the first connection hole may be formed to pass through the head and the insertion bar.

The second connection member may include a housing fastened to the second vacuum hole, disposed toward the first connection member, and in which a housing hole is formed; and a fixing tube installed in the housing hole and having a fixing hole through which the insertion bar of the first connection member is inserted and press-fitted.

The housing may be formed of a steel material, and the fixing tube may be formed of a silicone material.

A fixing inlet connected to the fixing hole may be formed in the fixing tube, and an internal space of the fixing inlet may be tapered toward the fixing hole.

A curved protrusion may be formed on an inner side surface of the fixing hole.

According to another aspect of the present disclosure, a substrate support includes a heating plate in which a heater and an electrical terminal connected to the heater are installed; a heater cup in which a bottom portion having a support pin supporting the heating plate is formed; and a vacuum hole connector connecting the heating plate and the heater cup, and supporting the heating plate, wherein the vacuum hole connector may include a first connection member fixed to a lower portion of a first vacuum hole of the heating plate, and in which a first connection hole is formed; and a second connection member installed in a second vacuum hole of the heater cup, and in which a second connection hole is formed, wherein the first connection member and the second connection member may include a metal material, and the first vacuum hole may communicate with the second vacuum hole through the first connection hole and the second connection hole, when the first connection member and the second connection member are assembled.

According to another aspect of the present disclosure, a substrate treatment apparatus may include a processing chamber including an upper body and a lower body to form a processing space therein; a substrate support disposed in the processing space, and supporting and heating a substrate; and a substrate lifting/lowering unit including a lifting/lowering pin lifted or lowered while penetrating the substrate support, and a pin driving member lifting or lowering the lifting/lowering pin, wherein the substrate support may include a heating plate in which a heater and an electrical terminal connected to the heater are installed; a heater cup in which a bottom portion having a support pin supporting the heating plate is formed; and a vacuum hole connector connecting the heating plate and the heater cup, and supporting the heating plate, wherein the vacuum hole connector may include a first connection member fixed to a lower portion of a first vacuum hole of the heating plate, and in which a first connection hole is formed; and a second connection member installed in a second vacuum hole of the heater cup, and in which a second connection hole is formed, wherein the first connection member and the second connection member may include a metal material, and the first vacuum hole may communicate with the second vacuum hole through the first connection hole and the second connection hole, when the first connection member and the second connection member are assembled.

### BRIEF DESCRIPTION OF DRAWINGS

The above and other aspects, features, and advantages of the present disclosure will be more clearly understood from the following in detailed description, taken conjunction with the accompanying drawings, in which:

FIG. 1 is a view illustrating a silicone rubber member

disposed between a heating cup and a heating plate, according to the prior art.

FIG. 2 is a perspective view illustrating a substrate treatment apparatus according to an embodiment of the present disclosure.

FIG. 3 is a view of the substrate treatment apparatus of FIG. 2, viewed from above.

FIG. 4 is a view of the substrate treatment apparatus of FIG. 3, viewed in an A-A direction.

FIG. 5 is a view of the substrate treatment apparatus of FIG. 3, viewed in a B-B direction.

FIG. 6 is a view illustrating a processing chamber including a substrate support according to an embodiment of the present disclosure.

FIG. 7 is a view illustrating an upper portion of a substrate support according to an embodiment of the present disclosure.

FIG. 8 is a cross-sectional view illustrating a state before a heating plate is assembled to a heater cup in the substrate support of FIG. 7.

FIG. 9 is a view illustrating the heater cup of FIG. 8.

FIG. 10 is a longitudinal cross-sectional view illustrating the vacuum hole connector disposed between the heater cup and the heating plate of FIG. 8.

FIG. 11 is a cross-sectional view illustrating that the heating plate of FIG. 10 is assembled to the heater cup and a first connection member of the heating plate is inserted and fixed into a second connection member of the heater cup.

### DETAILED DESCRIPTION

Hereinafter, with reference to the attached drawings, preferred embodiments will be described in detail such that those skilled in the art may easily practice the present disclosure. However, when describing preferred embodiments of the present disclosure in detail, and it is determined that a detailed description of a related known function or configuration may unnecessarily obscure the gist of the present disclosure, the detailed description will be omitted. In addition, the same symbols may be used throughout the drawings for parts that perform similar functions and actions.

In addition, in this specification, terms such as ‘on,’ ‘upper portion,’ ‘upper surface,’ ‘below,’ ‘lower portion,’ ‘lower surface,’ and the like may be based on the drawings, and may actually vary depending on a direction in which an element or a component is disposed.

In addition, throughout the specification, when a portion is said to be ‘connected’ to a different portion, this may not be only a case in which the portion is ‘directly connected’ to the different portion, but also a case in which the portion is ‘indirectly connected’ to the different portion with another component interposed therebetween. In addition, ‘including’ a certain component means that other elements may be further included, rather than excluding another component, unless specifically stated to the contrary.

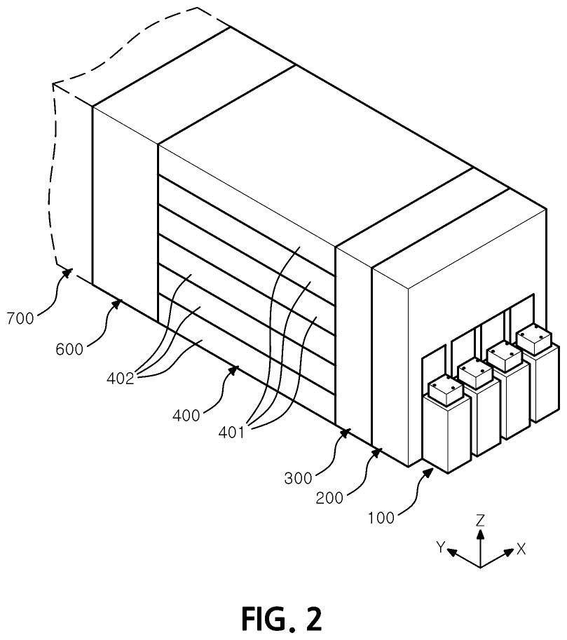

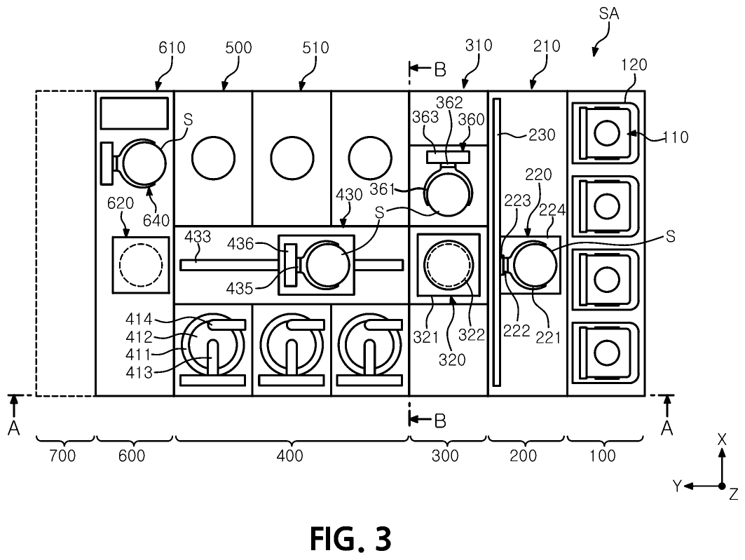

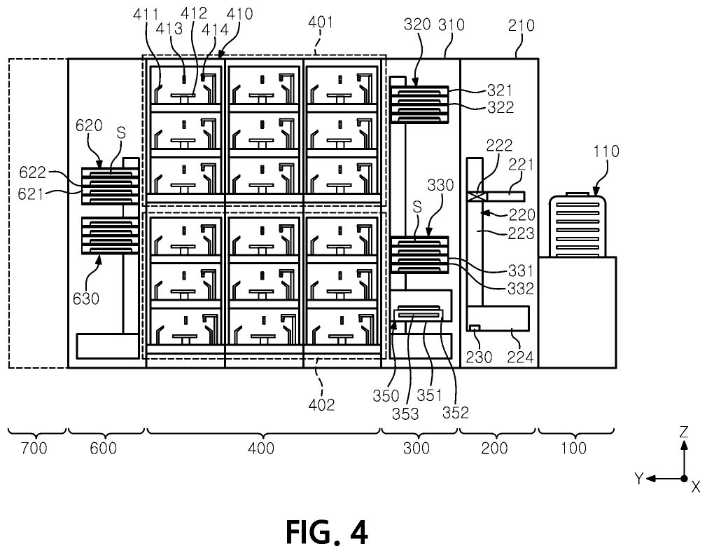

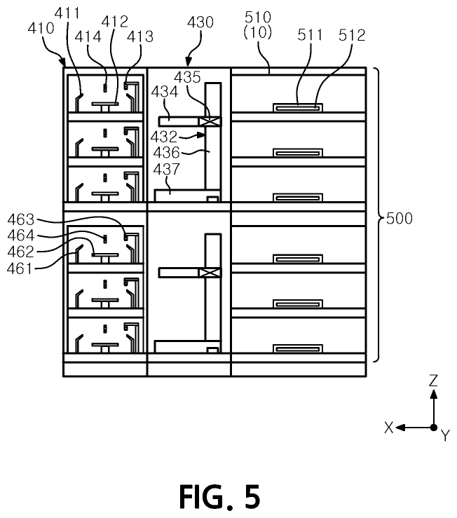

FIGS. 2 to 5 are views schematically illustrating a substrate treatment apparatus according to an embodiment of the present disclosure. FIG. 2 is a perspective view illustrating a substrate treatment apparatus, FIG. 3 is a view of the substrate treatment apparatus of FIG. 2, viewed from above FIG. 4 is a view of the substrate treatment apparatus of FIG. 3, viewed in an A-A direction, and FIG. 5 is a view of the substrate treatment apparatus of FIG. 3, viewed in a B-B direction.

Referring to FIGS. 2 to 5, a substrate treatment apparatus SA may include a load port 100, an index module 200, a buffer module 300, an applying/development module 400, an interface module 600, and a purge module 800. The load port 100, the index module 200, the buffer module 300, the applying/development module 400, and the interface module 600 may be sequentially arranged in a line in one direction.

Hereinafter, a direction in which the load port 100, the index module 200, the buffer module 300, the applying/development module 400, and the interface module 600 are arranged may be referred to as a first direction Y, a direction, perpendicular to the first direction Y, when viewed from above, may be referred to as a second direction X, and a direction, perpendicular to the first direction Y and the second direction X, may be referred to as a third direction Z.

A substrate S may move in a state accommodated in a cassette 110. The cassette 110 may have a structure that may be sealed from the outside. For example, a front opening unified pod (FOUP) having a door in a front direction may be used as the cassette 110.

Hereinafter, the load port 100, the index module 200, the buffer module 300, the applying/development module 400, and the interface module 600 will be described in detail.

The load port 100 may have a placing table 120 on which the cassette 110 in which the substrate S is accommodated is disposed. The placing table 120 may be provided in plural, and the plurality of placing tables 120 may be arranged in a row in the second direction X. FIG. 3 illustrates an example in which four placing tables 120 are provided, but the number thereof may be changed.

The index module 200 may transfer the substrate S between the cassette 110 disposed on the placing table 120 of the load port 100, and the buffer module 300. The index module 200 may include a frame 210, an index robot 220, and a guide rail 230. The frame 210 may be generally provided in a rectangular hexahedral shape having an empty interior, and may be disposed between the load port 100 and the buffer module 300. The frame 210 of the index module 200 may be provided on a lower height than a frame 310 of the buffer module 300. The index robot 220 and the guide rail 230 may be arranged in the frame 210. The index robot 220 may be provided such that a hand 221, which directly handles the substrate S, may move and rotate in the first direction Y, the second direction X, and the third direction Z. The index robot 220 may include the hand 221, an arm 222, a support 223, and a pedestal 224. The hand 221 may be fixedly installed on the arm 222. The arm 222 may be provided to as a stretchable structure or a rotatable structure. A longitudinal direction of the support 223 may be disposed in the third direction Z. The arm 222 may be coupled to the support 223 to be movable along the support 223. The support 223 may be fixedly coupled to the pedestal 224. The guide rail 230 may be provided such that a longitudinal direction thereof is disposed in the second direction X. The pedestal 224 may be coupled to the guide rail 230 to move linearly along the guide rail 230. In addition, although not illustrated, the frame 210 may be further provided with a door opener for opening and closing the door of the cassette 110.

The buffer module 300 may include the frame 310, a first buffer 320, a second buffer 330, a cooling chamber 350, and a first buffer robot 360. The frame 310 may be provided in a rectangular hexahedral shape having an empty interior, and may be disposed between the index module 200 and the applying/development module 400. The first buffer 320, the second buffer 330, the cooling chamber 350, and the first buffer robot 360 may be located in the frame 310. The cooling chamber 350, the second buffer 330, and the first buffer 320 may be sequentially arranged in the third direction Z from below. The first buffer 320 may be located on a height corresponding to an application module 401 of the applying/development module 400, and the second buffer 330 and the cooling chamber 350 may be located on a height corresponding to a development module 402 of the applying/development module 400. The first buffer robot 360 may be located at a certain distance from the second buffer 330, the cooling chamber 350, and the first buffer 320 in the second direction X. The first buffer 320 and the second buffer 330 may temporarily store a plurality of substrates S, respectively. The second buffer 330 may have a housing 331 and a plurality of supports 332. The supports 332 may be disposed in the housing 331, and may be spaced apart from each other in the third direction Z. One substrate S may be disposed on each of the supports 332. The housing 331 may have an opening in a direction in which the index robot 220 is provided and in a direction in which the first buffer robot 360 is provided, such that the index robot 220 and the first buffer robot 360 may load or unload the substrate S into or out of the support 332 in the housing 331. The first buffer 320 may have a generally similar structure to the second buffer 330. The housing 321 of the first buffer 320 may have an opening in a direction in which the first buffer robot 360 is provided, and in a direction in which an application robot 432 located in the application module 401 is provided. The number of supports 322 provided in the first buffer 320 may be the same as or different from the number of supports 332 provided in the second buffer 330. According to an example, the number of supports 332 provided in the second buffer 330 may be greater than the number of supports 322 provided in the first buffer 320.

The first buffer robot 360 may transport the substrate

S between the first buffer 320 and the second buffer 330, as illustrated in FIG. 3. The first buffer robot 360 may include a hand 361, an arm 362, and a support 363. The hand 361 may be fixedly installed on the arm 362. The arm 362 may be provided in a stretchable structure such that the hand 361 may move in the second direction X. The arm 362 may be coupled to the support 363 to move linearly along the support 363 in the third direction Z. The support 363 may have a length extending from a position corresponding to the second buffer 330 to a position corresponding to the first buffer 320. The support 363 may be provided to be longer in an upward direction or a downward direction. The first buffer robot 360 may be provided such that the hand 361 may be driven only in two axes in the second direction X and the third direction Z.

The cooling chambers 350 may cool the substrates S, respectively, as illustrated in FIG. 4. The cooling chamber 350 may include a housing 351 and a cooling plate 352. The cooling plate 352 may have an upper surface on which the substrate S is disposed, and a cooling means 353 cooling the substrate S. As the cooling means 353, various methods may be used, such as cooling using a coolant, cooling using a thermoelectric element, or the like. Additionally, the cooling chamber 350 may be provided with a lift pin assembly locating the substrate S on the cooling plate 352. The housing 351 may have an opening in a direction in which the index robot 220 is provided and in a direction in which a development robot provided in the development module 402 is provided, such that the index robot 220 and the developing robot provided in the development module 402 load or unload the substrate S to or from the cooling plate 352. Additionally, the cooling chamber 350 may be provided with doors opening and closing the above-described openings.

The application module 401 may include a process of applying a photosensitive liquid such as a photoresist to the substrate S, and a heat treatment process such as heating and cooling of the substrate S before and after a resist application process. The application module 401 may have an application chamber 410, a baking chamber unit 500, and a transfer chamber 430. The application chamber 410, the transfer chamber 430, and the baking chamber unit 500 may be sequentially arranged in the second direction X. For example, based on the transfer chamber 430, the application chamber 410 may be provided on one side of the transfer chamber 430, and the baking chamber unit 500 may be provided on the other side of the transfer chamber 430.

The application chamber 410 may be provided in plural, and may be provided in plural, respectively, in the first direction Y and the third direction Z. The baking chamber unit 500 may include a plurality of baking chambers 510, and the plurality of baking chambers 510 may be provided in plural, respectively, in the first direction Y and the third direction Z. The transfer chamber 430 may be located parallel to the first buffer 320 of the buffer module 300 in the first direction Y. An application robot 432 and a guide rail 433 may be located in the transfer chamber 430. The transfer chamber 430 may have a generally rectangular shape. The application robot 432 may transfer the substrate S between the baking chamber 510, the applicator chamber 410, and the first buffer 320 of the buffer module 300.

The guide rail 433 may be disposed such that a longitudinal direction thereof is parallel to the first direction Y. The guide rail 433 may guide the application robot 432 to move linearly in the first direction Y. As illustrated in FIG. 5, the application robot 432 may have a hand 434, an arm 435, a support 436, and a pedestal 437. The hand 434 may be fixedly installed on the arm 435. The arm 435 may be provided as a stretchable structure such that the hand 434 may move in a horizontal direction. The support 436 may be provided such that a longitudinal direction thereof is disposed in the third direction Z. The arm 435 may be coupled to the support 436 to move linearly along the support 436 in the third direction Z. The support 436 may be fixedly coupled to the pedestal 437, and the pedestal 437 may be coupled to the guide rail 433 to be movable along the guide rail 433.

All of the application chambers 410 may have the same structure, but types of processing liquids used in the application chambers 410 may be different. As the processing liquids, a processing liquid for forming a photoresist film or an anti-reflection film may be used.

The application chamber 410 may apply the processing liquid to the substrate S. The application chamber 410 may have a cup 411, a substrate support 412, and a nozzle 413. The cup 411 may have a shape opened in an upward direction. The substrate support 412 may be located in the cup 411, and may support the substrate S. The substrate support 412 may be provided to be rotatable. The nozzle 413 may supply the processing liquid onto the substrate S disposed on the substrate support 412. The processing liquid may be applied to the substrate S using a spin coat method. In addition, the application chamber 410 may include a nozzle 414 for supplying a cleaning liquid such as deionized water (DIW) to clean a surface of the substrate S on which the processing liquid is applied, and a back rinse nozzle (not illustrated) for cleaning a lower surface of the substrate S may be optionally further provided in the application chamber 410.

In the baking chamber 510, a substrate support 511 and a heater 512 built into the substrate support 511 may be installed in a processing space therein, and the application robot 432 may heat treat the substrate S when the substrate S is seated on the substrate support 511. For example, in the baking chamber 510, a prebaking process for removing an organic matter or moisture from the surface of the substrate S by heating the substrate S to a predetermined temperature, before applying a photoresist, a soft baking process performed after applying the photoresist to the substrate S, or the like may be performed, and a cooling process performed to cool the substrate S after each heating process, or the like may be performed.

The interface module 600 may connect the applying/development module 400 to an exposure device 700 externally. The interface module 600 may include an interface frame 610, a first interface buffer 620, a second interface buffer 630, and a transfer robot 640, and, after an operation of the applying/development module 400 is completed, the transfer robot 640 may transfer the substrate returned to the first and second interface buffers 620 and 630 to the exposure device 700. The first interface buffer 620 may include a housing 621 and a support 622, and the transfer robot 640 may load/unload the substrate S into/out of the support 622.

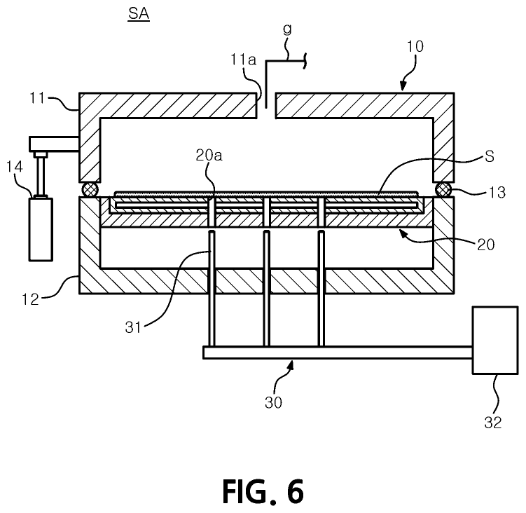

FIG. 6 is a view illustrating a processing chamber including a substrate support according to an embodiment of the present disclosure.

Referring to the drawing, a substrate treatment apparatus SA of the present disclosure may include a processing chamber 10, a substrate support 20, and a substrate lifting/lowering unit 30.

A processing space for heat treating a substrate S may be formed in the processing chamber 10. The processing chamber 10 may include an upper body 11 and a lower body 12 to form the processing space. A sealing member 13 may be installed on one of the upper body 11 or the lower body 12, and a body lifting/lowering member 14 may be installed on the upper body 11. A gas supply line g may be connected to an upper hole 11a of the upper body 11 to supply gas to the substrate S. The gas may be supplied to the processing space during heating of the substrate S, to improve an adhesion rate of a photoresist (photosensitive solution) to the substrate. Such a processing chamber 10 may be a baking chamber (510 in FIG. 5), as described above, but is not limited to the above-described description, and may be used in any process for heating the substrate.

Additionally, the substrate support 20 may be disposed in the processing space, and may support and heat the substrate S, which will be described later.

The substrate lifting/lowering unit 30 may include a lifting/lowering pin 31 and a pin driving member 32. The lifting/lowering pin may be lifted or lowered while penetrating the substrate support 20 through a hole 20a of the substrate support 20, and the pin driving member 32 may be connected to the lifting/lowering pin 31 to lift and lower the lifting/lowering pin 31. The lifting/lowering pin 31 may lift the substrate S while supporting the substrate S, when lifted by the pin driving member 32.

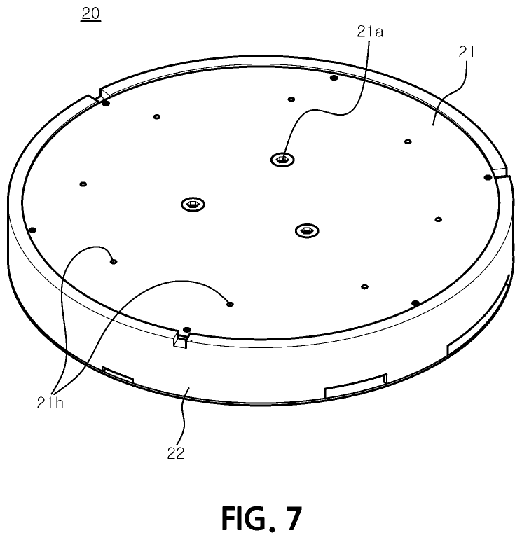

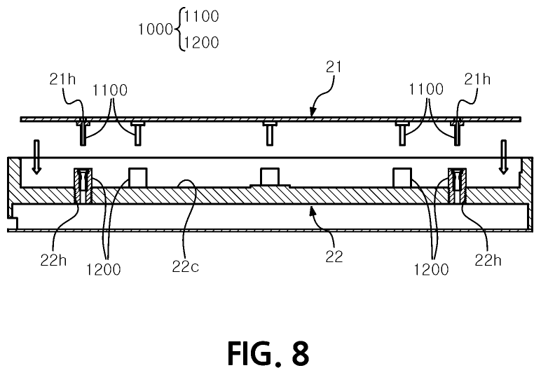

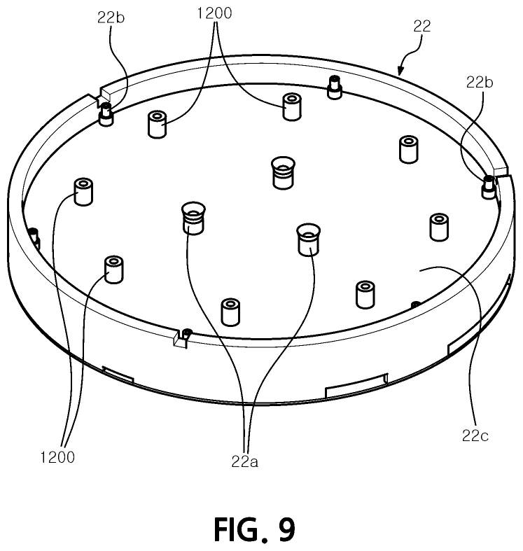

FIG. 7 is a view illustrating an upper portion of a substrate support according to an embodiment of the present disclosure, FIG. 8 is a cross-sectional view illustrating a state before a heating plate is assembled to a heater cup in the substrate support of FIG. 7, and FIG. 9 is a view illustrating the heater cup of FIG. 8.

Referring to the drawings, a substrate support 20 may include a heating plate 21, a heater cup 22, and a vacuum hole connector 1000.

The heating plate 21 may have a circular plate shape, may be a portion on which a substrate is mounted on an upper surface, and may serve to heat the substrate on which a heater is mounted and seated.

The heating plate 21 may be formed of a ceramic material. In general, in a baking process of 200° C. or lower, a ceramic member having a thickness of about 2 mm to 4 mm may be used, and in a baking process at a relatively high-temperature of about 400° C., a ceramic member having a thickness of about 5 mm to 20 mm may be used. Additionally, a pin hole 21a, which may be a passage through which a lifting/lowering pin 31, such as in FIG. 7, is lifted, may be formed in the heating plate 21. A first vacuum hole 21h may be formed in the heating plate 21 to fix the substrate. The first vacuum hole 21h may be provided in plural to have a concentric circle shape. The first vacuum hole 21h may be a passage through which air is intaken, and may be used to adsorb the substrate.

The heater cup 22 may be a structure supporting and surrounding the heating plate 21, and may have a bottom portion 22c through which a hole cylinder 22a is installed in communication with the pin hole 21a of the heating plate 21. A support pin 22b supporting the heating plate 21 may be installed on the bottom portion 22c. Additionally, a second vacuum hole 22h may be formed in the heater cup 22 to fix the substrate. The second vacuum hole 22h may be provided in plural to have a concentric circle shape, to correspond to the first vacuum holes 21h of the heating plate 21. The second vacuum hole 22h may be a passage through which air is intaken, together with the first vacuum hole 21h, may be used to adsorb the substrate, and may be connected to a vacuum line (not illustrated) disposed below the heater cup 22.

The vacuum hole connector 1000 may be disposed between the heating plate 21 and the heater cup 22. As the first vacuum hole 21h and the second vacuum hole 22h are disposed closer to the center of the heating plate 21 than the support pin 22b such that the vacuum hole connector 1000 is disposed relatively closer to a center of the heating plate 21 than the support pin 22b, the support pin 22b may support an edge of the heating plate 21 and the vacuum hole connector 1000 may support a center side of the heating plate 21. Additionally, the vacuum hole connector 1000 may serve to connect the first vacuum hole 21h and the second vacuum hole 22h. Therefore, a passage through which air is intaken and including the vacuum line, the second vacuum hole 22h of the heater cup 22, the vacuum hole connector 1000, and the first vacuum hole 21h of the heating plate 21, may be formed to adsorb and fix the substrate disposed on the heating plate 21.

In this manner, the substrate may be vacuum adsorbed through the vacuum hole connector 1000 to unfold a bent substrate in a flat state. When a photoresist is used at a high viscosity, the substrate may be shrink and bent. The substrate may be fixed to the heating plate 21 while transforming a bent shape of the substrate into a flat shape through vacuum adsorption.

Prior to providing a detailed description of the vacuum hole connector according to the present disclosure, a silicone rubber tube connecting the first vacuum hole and the second vacuum hole in the prior art will be described as follows.

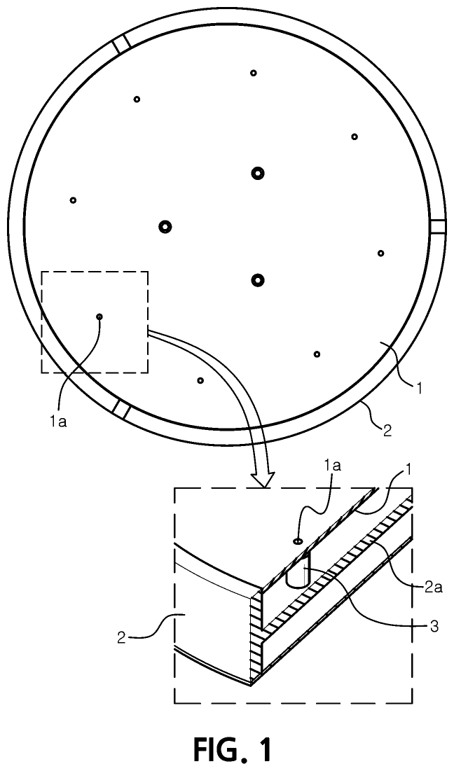

FIG. 1 is a view illustrating a silicone rubber member disposed between a heating cup and a heating plate, according to the prior art.

Referring to the drawing, a first vacuum hole la may be formed in a heating plate 1, and a second vacuum hole (not illustrated) may be formed in a heater cup 2. In this case, the first vacuum hole la may be formed in plural to have a concentric circle shape in the heating plate 1, and correspondingly, the second vacuum hole (not illustrated) may be formed in plural to have a concentric circle shape in the heater cup 2.

A silicone rubber tube 3 may be disposed between the heating plate 1 and the heater cup 2.

Specifically, the silicone rubber tube 3 may have a structure in close contact with an upper surface of the heating plate 1 by seating the heating plate 1 on the heater cup 2 while being installed on a bottom portion 2a of the heater cup 2.

The silicone rubber tube 3 may be disposed between the first vacuum hole la of the heating plate 1 and the second vacuum hole (not illustrated) of the heater cup 2, to communicate between the first vacuum hole la and the second vacuum hole.

The silicone rubber tube 3 may have limitations when used in a high-temperature substrate processing process. For example, the silicone rubber tube 3 may have various problems when used in a high-temperature substrate processing process, for example, a high-temperature baking process, due to a heat resistance limit temperature of silicone.

Specifically, when the silicone rubber tube 3 is used in the high-temperature substrate processing process, the silicone rubber tube 3 may melt and be damaged. Therefore, a leakage phenomenon may occur to prevent smooth vacuum adsorption, and to decrease a lifespan thereof, and, furthermore, the silicone rubber tube 3 should be frequently replaced. In addition, the silicone rubber tube 3 may cause occurrence of particles that cause process defects, when cured after the high-temperature process.

To overcome the problems described above, a vacuum hole connector according to an embodiment of the present disclosure may be configured as follows.

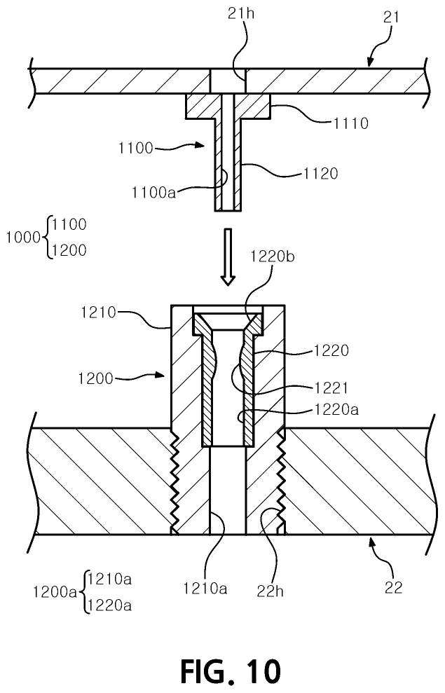

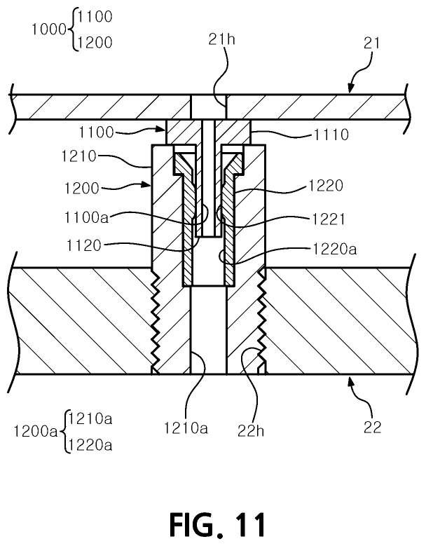

FIG. 10 is a longitudinal cross-sectional view illustrating the vacuum hole connector disposed between the heater cup and the heating plate of FIG. 8, and FIG. 11 is a cross-sectional view illustrating that the heating plate of FIG. 10 is assembled to the heater cup and a first connection member of the heating plate is inserted and fixed into a second connection member of the heater cup.

Referring to the drawings, a vacuum hole connector 1000 according to an embodiment of the present disclosure may include a first connection member 1100 and a second connection member 1200.

The first connection member 1100 may be fixed to a lower portion of a first vacuum hole 21h of a heating plate 21, and a first connection hole 1100a may be formed therein.

The second connection member 1200 may be installed in a second vacuum hole 22h of a heater cup 22, and may be attached to the first connection member 1100, and a second connection hole 1200a may be formed therein.

The first connection member 1100 and the second connection member 1200 may include a metal material, and when the first connection member and the second connection member are assembled, the first connecting hole 1100a and the second connecting hole 1200a may be connected to each other through the first vacuum hole 21h and the second vacuum hole 22h.

In this manner, the first connection member 1100 and the second connection member 1200, which communicate with the first vacuum hole 21h and the second vacuum hole 22h, may include the metal material, to be used in a high-temperature substrate processing process, without any damage due to high heat. For example, since the metal material of the first connection member 1100 and the metal material of the second connection member 1200 have a higher heat resistance limit temperature than a conventional silicone rubber tube, the vacuum hole connector 1000 of the present disclosure may be used without in the high-temperature substrate processing process.

Therefore, the vacuum hole connector 1000 of the present disclosure may prevent leakage caused by thermal damage, to completely maintain a vacuum adsorption function and to relatively increase a lifespan thereof. Furthermore, unlike a conventional silicone rubber pipe 3, occurrence of particles may be also prevented.

In addition, the first connection member 1100 formed of the metal material and the heating plate 21 formed of a ceramic material may be joined to each other by active metal brazing (AMB), to form a joint of heterogeneous materials. The active metal brazing method may add an active element to a brazing material to heat the brazing material in a vacuum, to form a reaction layer on a surface of the heating plate 21 formed of the ceramic material. As a result, wettability and adhesion of the brazing material may be improved, and the first connection member 1100 formed of the metal material and the heating plate 21 formed of the ceramic material may be joined to each other.

Therefore, in the vacuum hole connector 1000 of the present disclosure, the first connection member 1100 formed of the metal material may be firmly fixed to the heating plate 21 formed of the ceramic material, to prevent occurrence of leakage between the heating plate 21 and the vacuum hole connector 1000 due to external force or a high-temperature.

The vacuum hole connector 1000 of the present disclosure may have a structure in which the first connection member 1100 is inserted into and fixed to the second connection member 1200.

The first connection member 1100 may include a head 1110 and an insertion bar 1120.

First, the head 1110 may be joined to the heating plate 21. For example, the head 1110 of the first connection member 1100 may be a portion joined to the heating plate 21 by active metal brazing, as described above.

Additionally, the insertion bar 1120 may extend from the head 1110, and may be inserted into the second connection hole 1200a of the second connection member 1200.

In addition, the first connection hole 1100a of the first connection member 1100 may have a structure formed to penetrate through the head 1110 and the insertion bar 1120.

The second connection member 1200 may include a housing 1210 and a fixing tube 1220.

First, the housing 1210 may be fastened to the second vacuum hole 22h. As an example, a thread line may be formed on an inner peripheral surface of the second vacuum hole 22h of the heater cup 22, and correspondingly, a thread line may be formed on an outer peripheral surface of a lower portion of the housing 1210. Therefore, the housing 1210 may be firmly fixed by screwing into the second vacuum hole 22h of the heater cup 22.

The housing 1210 may be disposed toward the first connection member 1100, and a housing hole 1210a may be formed therein. For example, the housing 1210 may have a structure extending upward, in the drawings, in a state fastened to the second vacuum hole 22h, such that when the heating plate 21 is seated, the housing 1210 may be attached to the first connection member 1100 disposed thereon.

Additionally, the fixing tube 1220 may be installed in the housing hole 1210a of the housing 1210. As an example, the fixing tube 1220 may be inserted into the housing hole 1210a, and may be installed in a pressure-fitting manner. As another example, when the housing 1210 is formed of a steel material and the fixing tube 1220 is formed of a silicone material, after the housing 1210 formed of the steel material is manufactured, the fixing tube 1220 may be formed by injection into the housing 1210. Furthermore, an installation structure of the fixing tube 1220 to the housing hole 1210a is not limited to the present disclosure, and any conventional installation structure may be used as long as the fixing tube 1220 is firmly fixed.

A fixing hole 1220a into which the insertion bar 1120 of the first connection member 1100 is inserted and press-fitted may be formed in the fixing tube 1220. Therefore, when the insertion bar 1120 of the first connection member 1100 is inserted into the second connection member 1200, the insertion bar 1120 may be inserted and pressed into the fixing hole 1220a of the fixing 1220 installed in the housing 1210 of the second connection member 1200, such that the first connection member 1100 and the second connection member 1200 are assembled and fixed to each other.

In this case, the second connection hole 1200a of the second connection member 1200 may include the housing hole 1210a and the fixing hole 1220a.

Additionally, the housing 1210 may be formed of a steel material, and the fixing tube 1220 may be formed of a silicone material.

The silicone material of the fixing tube 1220 may be an elastic material, and when the insertion bar 1120 of the first connection member 1100 is inserted and press-fitted into the fixing hole 1220a of the fixing tube 1220, the insertion bar 1120 may be inserted smoothly and easily into the fixing hole 1220a. In addition, fixing force of the insertion bar 1120 with respect to the fixing tube 1220 may be improved.

In this case, the fixing tube 1220 formed of the silicone material may have a structure surrounded by the housing 1210 formed of the steel material and the first connection member 1100 formed of the steel material, to not receive thermal damage even during a high-temperature substrate processing process. For example, the fixing tube 1220 formed of the silicone material may be substantially affected only by relatively low temperatures because the high-temperature during the substrate processing process is blocked by the housing 1210 and the first connection member 1100 formed of the steel material.

Furthermore, heat-resistant silicone may be used as the silicone material of the fixing tube 1220.

In addition, a fixing inlet 1220b connected to the fixing hole 1220a may be formed in the fixing tube 1220, and an internal space of the fixing inlet 1220b may be tapered toward the fixing hole 1220a.

The fixing inlet 1220b formed to be tapered in this manner may guide the insertion bar 1120 of the first connection member 1100 into the fixing hole 1220a.

In addition, a curved protrusion 1221 may be formed on an inner side surface of the fixing hole 1220a.

The curved protrusion 1221 may be formed to protrude from the inner side surface of the fixing hole 1220a, and may have a surface having a curved shape rather than an angular shape. As an example, the curved protrusion 1221 may be formed in a convex shape on the inner side surface of the fixing hole 1220a.

In this manner, when the insertion bar 1120 of the first connection member 1100 is inserted into the fixing hole 1220a, the curved protrusion 1221 may further improve fixation power of the insertion bar 1120 with respect to the fixing hole 1220a, while being smoothly inserted.

As a result, the vacuum hole connector 1000 of the present disclosure may be used in a high-temperature substrate processing process, without damage due to high heat, because the first connection member 1100 and the second connection member 1200 include a metal material. Therefore, the vacuum hole connector 1000 of the present disclosure may prevent leakage caused by thermal damage, to completely maintain a vacuum adsorption function and to relatively increase a lifespan thereof. Furthermore, unlike a conventional silicone rubber pipe 3, the vacuum hole connector 1000 of the present disclosure may prevent occurrence of particles.

Additionally, in the present disclosure, the first connection member 1100 formed of a metal material and the heating plate 21 formed of a ceramic material may be joined to each other by active metal brazing (AMB), to form a joint of heterogeneous materials. For this reason, in the vacuum hole connector 1000 of the present disclosure, the first connection member 1100 formed of the metal material may be firmly fixed to the heating plate 21 formed of the ceramic material, to prevent occurrence of leakage between the heating plate 21 and the vacuum hole connector 1000 due to external force or a high-temperature.

In addition, according to the present disclosure, the insertion bar 1120 of the first connection member 1100 may be inserted and press-fitted into the fixing tube 1220 formed of the silicone material, built into the housing 1210 formed of the steel material, to insert smoothly and easily the insertion bar 1120 into the fixing tube 1220, and, in addition, to improve fixing force of the insertion bar 1120 with respect to the fixing tube 1220.

A vacuum hole connector of the present disclosure may be used in a high-temperature substrate processing process, without damage by high heat, because first and second connection members include a metal material. As a result, the vacuum hole connector of the present disclosure may prevent leakage caused by thermal damage, to maintain a vacuum adsorption function, increase a lifespan, and prevent occurrence of particles.

In addition, according to the present disclosure, a first connection member formed of a metal material and a heating plate formed of a ceramic material may be joined to each other by active metal brazing (AMB), to form a joint of heterogeneous materials. Therefore, occurrence of leakage between the heating plate and the vacuum hole connector may be prevented.

In addition, in the present disclosure, an insertion bar of a first connection member may be inserted and press-fitted into a fixing tube formed of a silicone material, built into a housing formed of a steel material, to smoothly and easily insert the insertion bar into the fixing tube, and, in addition, to improve fixing force of the insertion bar with respect to the fixing tube.

While example embodiments have been illustrated and described above, it will be apparent to those skilled in the art that modifications and variations could be made without departing from the scope of the present disclosure as defined by the appended claims.

What is claimed is:

1. A vacuum hole connector comprising:
a first connection member fixed to a lower portion of a first vacuum hole of a heating plate, and in which a first connection hole is formed; and
a second connection member installed in a second vacuum hole of a heater cup, attached to the first connection member, and in which a second connection hole is formed,
wherein the first connection member and the second connection member include a metal material, and the first vacuum hole communicates with the second vacuum hole through the first connection hole and the second connection hole, when the first connection member and the second connection member are assembled.

2. The vacuum hole connector of claim 1, wherein the first connection member formed of the metal material is joined to the heating plate formed of a ceramic material by active metal brazing (AMB), to form a joint of heterogeneous materials.

3. The vacuum hole connector of claim 1, wherein the first connection member comprises:
a head joined to the heating plate; and
an insertion bar extending from the head and inserted into the second connection hole of the second connection member,
wherein the first connection hole is formed to pass through the head and the insertion bar.

4. The vacuum hole connector of claim 3, wherein the second connection member comprises:
a housing fastened to the second vacuum hole, disposed toward the first connection member, and in which a housing hole is formed; and
a fixing tube installed in the housing hole and having a fixing hole through which the insertion bar of the first connection member is inserted and press-fitted,
wherein the second connection hole includes the housing hole and the fixing hole.

5. The vacuum hole connector of claim 4, wherein the housing is formed of a steel material, and the fixing tube is formed of a silicone material.

6. The vacuum hole connector of claim 4, wherein a fixing inlet connected to the fixing hole is formed in the fixing tube, and an internal space of the fixing inlet is tapered toward the fixing hole.

7. The vacuum hole connector of claim 4, wherein a curved protrusion is formed on an inner side surface of the fixing hole.

8. A substrate support comprising:
a heating plate in which a heater and an electrical terminal connected to the heater are installed;
a heater cup in which a bottom portion having a support pin supporting the heating plate is formed; and
a vacuum hole connector connecting the heating plate and the heater cup, and supporting the heating plate,
wherein the vacuum hole connector includes:
a first connection member fixed to a lower portion of a first vacuum hole of the heating plate, and in which a first connection hole is formed; and
a second connection member installed in a second vacuum hole of the heater cup, and in which a second connection hole is formed,
wherein the first connection member and the second connection member include a metal material, and the first vacuum hole communicates with the second vacuum hole through the first connection hole and the second connection hole, when the first connection member and the second connection member are assembled.

9. The substrate support of claim 8, wherein the first connection member formed of the metal material is joined to the heating plate formed of a ceramic material by active metal brazing (AMB), to form a joint of heterogeneous materials.

10. The substrate support of claim 8, wherein the first connection member comprises:
a head joined to the heating plate; and
an insertion bar extending from the head and inserted into the second connection hole of the second connection member,
wherein the first connection hole is formed to pass through the head and the insertion bar.

11. The substrate support of claim 10, wherein the second connection member comprises:
a housing fastened to the second vacuum hole, disposed toward the first connection member, and in which a housing hole is formed; and
a fixing tube installed in the housing hole and having a fixing hole through which the insertion bar of the first connection member is inserted and press-fitted,
wherein the second connection hole includes the housing hole and the fixing hole.

12. The substrate support of claim 11, wherein the housing is formed of a steel material, and the fixing tube is formed of a silicone material.

13. The substrate support of claim 11, wherein a fixing inlet connected to the fixing hole is formed in the fixing tube, and an internal space of the fixing inlet is tapered toward the fixing hole.

14. The substrate support of claim 11, wherein a curved protrusion is formed on an inner side surface of the fixing hole.

15. A substrate treatment apparatus comprising:
a processing chamber including an upper body and a lower body to form a processing space therein;
a substrate support disposed in the processing space, and supporting and heating a substrate; and
a substrate lifting/lowering unit including a lifting/lowering pin lifted or lowered while penetrating the substrate support, and a pin driving member lifting or lowering the lifting/lowering pin,
wherein the substrate support includes:
a heating plate in which a heater and an electrical terminal connected to the heater are installed;
a heater cup in which a bottom portion having a support pin supporting the heating plate is formed; and
a vacuum hole connector connecting the heating plate and the heater cup, and supporting the heating plate,
wherein the vacuum hole connector includes:
a first connection member fixed to a lower portion of a first vacuum hole of the heating plate, and in which a first connection hole is formed; and
a second connection member installed in a second vacuum hole of the heater cup, and in which a second connection hole is formed,
wherein the first connection member and the second connection member include a metal material, and the first vacuum hole communicates with the second vacuum hole through the first connection hole and the second connection hole, when the first connection member and the second connection member are assembled.

16. The substrate treatment apparatus of claim 15, wherein the first connection member formed of the metal material is joined to the heating plate formed of a ceramic material by active metal brazing (AMB), to form a joint of heterogeneous materials.

17. The substrate treatment apparatus of claim 15, wherein the first connection member comprises:
a head joined to the heating plate; and
an insertion bar extending from the head and inserted into the second connection hole of the second connection member,
wherein the first connection hole is formed to pass through the head and the insertion bar.

18. The substrate treatment apparatus of claim 17, wherein the second connection member comprises:
a housing fastened to the second vacuum hole, disposed toward the first connection member, and in which a housing hole is formed; and
a fixing tube installed in the housing hole and having a fixing hole through which the insertion bar of the first connection member is inserted and press-fitted,
wherein the second connection hole includes the housing hole and the fixing hole.

19. The substrate treatment apparatus of claim 18, wherein the housing is formed of a steel material, and the fixing tube is formed of a silicone material.

20. The substrate treatment apparatus of claim 18, wherein a fixing inlet connected to the fixing hole is formed in the fixing tube, and an internal space of the fixing inlet is tapered toward the fixing hole, and
a curved protrusion is formed on an inner side surface of the fixing hole.
